(19) United States
(12) Patent Application Publication
(10) Pub. No.: US 2025/0255154 A1
(43) Pub. Date: Aug. 7, 2025

(54) DISPLAY PANEL AND DISPLAY DEVICE

(71) Applicants: Hefei Visionox Technology Co., Ltd., Hefei (CN); KunShan Go-Visionox Opto-Electronics Co., Ltd, Kunshan (CN)

(72) Inventors: Yongqiang DU, Hefei (CN); Yuan YAO, Hefei (CN); Xiaoxi SUN, Hefei (CN); Xuejing ZHU, Hefei (CN); Manli CHEN, Hefei (CN); Shizhen FENG, Hefei (CN)

(73) Assignees: Hefei Visionox Technology Co., Ltd., Hefei (CN); KunShan Go-Visionox Opto-Electronics Co., Ltd, Kunshan (CN)

(21) Appl. No.: 18/754,869

(22) Filed: Jun. 26, 2024

(30) Foreign Application Priority Data
Feb. 7, 2024 (CN) 202410176048.1

(51) Int. Cl. H10K 59/80; H10K 59/122

(52) U.S. Cl. CPC H10K 59/874; H10K 59/122; H10K 59/873

(57) ABSTRACT

A display panel includes a display region and a non-display region, and further includes a substrate, a light-emitting unit, a separating structure, a packaging layer and a dam structure. The light-emitting unit is arranged on a side of the substrate and located within the display region; the separating structure is located on the side of the substrate and within the display region, and the separating structure is provided with at least one separating opening to accommodate the light-emitting unit; the packaging layer includes an organic packaging sub-layer covering the light-emitting unit; the dam structure is arranged on a side of the substrate and located within the non-display region, the dam structure includes a first dam, and the first dam includes a first metal layer.

### CROSS REFERENCE TO RELATED APPLICATION

This application claims a priority of Chinese Patent Application No. 202410176048.1, filed on Feb. 7, 2024, titled with “DISPLAY PANEL AND DISPLAY DEVICE”, which is incorporated herein in its entirety.

### TECHNICAL FIELD

The present application relates to the technical field of display, and in particular to a display panel and a display device.

### BACKGROUND

A flat display device based on the technical of Organic Light Emitting Diode (OLED), Light Emitting Diode (LED) or the like has the advantages such as high image quality, low power consumption, thin body and wide application range, thus is widely used in various consumer electronic products such as a mobile phone, a television, a laptop and a desktop computer, and becomes a main stream in a display device. However, at present, the reliability of the OLED display product needs to be improved.

### SUMMARY

Embodiments of the present application provide a display panel and a display device, that can reduce the risk of moisture and oxygen intrusion caused by the overflow of a packaging material in an organic packaging sub-layer, and improve the reliability of the product.

In an aspect, embodiments of the present application provide a display panel including a display region and a non-display region, and further including a substrate, at least one light-emitting unit, a separating structure, a packaging layer and a dam structure. The light-emitting unit is arranged on a side of the substrate and located within the display region; the separating structure is arranged on the side of the substrate and located within the display region, and the separating structure is provided with at least one separating opening to accommodate the light-emitting unit; the packaging layer includes an organic packaging sub-layer covering the light-emitting unit; the dam structure is arranged on the side of the substrate and located within the non-display region, the dam structure includes a first dam, and the first dam includes a first metal layer.

In some embodiments, the first dam further includes a first insulating layer stacked with the first metal layer;

optionally, the display panel includes a driving circuit layer arranged on the side of the substrate, the driving circuit layer includes a first conductive layer, a second conductive layer, a third conductive layer and a fourth conductive layer arranged in a stacked manner, and the first metal layer is formed with the same material and at a same layer as at least one of the first conductive layer, the second conductive layer, the third conductive layer or the fourth conductive layer.

In some embodiments, the dam structure further includes a second dam adjacent to the first dam, and an overflow groove is formed between the first dam and the second dam;

optionally, the second dam is located on a side of the first dam away from the display region, and a height of the second dam is higher than a height of the first dam; and

optionally, the dam structure is arranged to surround the display region.

In some embodiments, the second dam includes a second metal layer and a second insulating layer stacked with the second metal layer;

optionally, the second metal layer is formed with the same material and at a same layer as at least one of the first conductive layer, the second conductive layer, the third conductive layer or the fourth conductive layer;

optionally, the first metal layer is spaced apart from the second metal layer;

optionally, the first metal layer is conducted with the second metal layer;

optionally, the first metal layer includes a first metal sub-layer and a second metal sub-layer sequentially stacked in a direction away from the substrate, the first metal sub-layer and the third conductive layer are arranged in the same layer and formed with the same material, and the second metal sub-layer and the fourth conductive layer are arranged in the same layer and formed with the same material; and optionally, the second metal layer includes a third metal sub-layer and a fourth metal sub-layer sequentially stacked in a direction away from the substrate.

In some embodiments, the first metal sub-layer and the third metal sub-layer are arranged in the same layer and conducted with each other; and

optionally, the first metal sub-layer, the third metal sub-layer and the third conductive layer are arranged in the same layer and formed with the same material.

In some embodiments, the second metal sub-layer and the fourth metal sub-layer are arranged in the same layer and conducted with each other; and

optionally, the second metal sub-layer, the fourth metal sub-layer and the fourth conductive layer are arranged in the same layer and formed with the same material.

In some embodiments, the dam structure further includes a connecting layer, that is arranged between the first dam and the second dam and conducts the first metal layer with the second metal layer;

optionally, the connecting layer includes a conductive region and a via hole region, the conductive region conducts the first metal layer with the second metal layer, the via hole region is provided with a via hole in a direction perpendicular to the substrate, and the overflow groove includes the via hole; and

optionally, the connecting layer includes a plurality of conductive regions and a plurality of via hole regions, and the plurality of conductive regions and the plurality of via hole regions are arranged alternately in an extending direction of an edge of the display region.

In some embodiments, the first insulating layer includes a first organic insulating sub-layer and a first inorganic insulating sub-layer; the first metal layer, the first organic insulating sub-layer and the first inorganic insulating sub-layer are arranged in a stacked manner; the second insulating layer includes a second organic insulating sub-layer and a second inorganic insulating sub-layer, and the second metal layer, the second organic insulating sub-layer and the second inorganic insulating sub-layer are arranged in a stacked manner.

In some embodiments, the display panel further includes a first planarization layer located within the display region, and the first planarization layer, the first organic insulating sub-layer and at least a portion of the second organic insulating sub-layer are arranged in the same layer and formed with the same material;

optionally, the display panel further includes a second planarization layer located within the display region, the second organic insulating sub-layer includes a first sub-layer and a second sub-layer, the first sub-layer and the first planarization layer are arranged in the same layer and formed with the same material, and the second sub-layer and the second planarization layer are arranged in the same layer and formed with the same material;

optionally, the second sub-layer extends from one end of the third metal sub-layer to cover one portion of the third metal sub-layer, the fourth metal sub-layer covers the other portion of the third metal sub-layer, and the first sub-layer covers the second sub-layer and the second metal layer; and optionally, the first organic insulating sub-layer covers the first metal layer.

In some embodiments, the display panel further includes a pixel-defining layer located within the display region, the pixel-defining layer includes a pixel-defining portion and a pixel opening formed and enclosed by the pixel-defining portion, the pixel opening is configured to arrange the light-emitting unit, and the separating structure is arranged on a side of the pixel-defining portion away from the substrate, and the first inorganic insulating sub-layer, the second inorganic insulating sub-layer and the pixel-defining layer are arranged in the same layer and formed with the same material;

optionally, the display panel further includes a third inorganic insulating sub-layer arranged between the first dam and the second dam, the third inorganic insulating sub-layer, the first inorganic insulating sub-layer, the second inorganic insulating sub-layer and the pixel-defining layer are arranged in the same layer and formed with the same material, and the overflow groove is located on a side of the third inorganic insulating sub-layer away from the substrate; and

optionally, the display panel further includes a third insulating layer, that is located between the dam structure and the substrate in the direction perpendicular to the substrate, the third inorganic insulating sub-layer is attached to a side of the third insulating layer away from the substrate when the first metal layer is spaced apart from the second metal layer, and the third inorganic insulating sub-layer is attached to a side of the connecting layer away from the substrate when the connecting layer conducts the first metal layer with the second metal layer.

In some embodiments, both an orthographic projection of the first metal layer on the substrate and an orthographic projection of the first organic insulating sub-layer on the substrate are located within an orthographic projection of the first inorganic insulating sub-layer on the substrate, and both an orthographic projection of the second metal layer on the substrate and an orthographic projection of the second organic insulating sub-layer on the substrate are located within an orthographic projection of the second inorganic insulating sub-layer on the substrate; and

optionally, the packaging layer further includes a second inorganic packaging sub-layer covering the organic packaging sub-layer, the second inorganic packaging sub-layer extends to the non-display region and covers the dam structure, and an orthographic projection of a portion of the second inorganic packaging sub-layer within the non-display region on the substrate overlaps with both an orthographic projection of the first inorganic insulating sub-layer on the substrate and an orthographic projection of the second inorganic insulating sub-layer on the substrate.

In a second aspect, embodiments of the present application further provide a display panel including a display region and a non-display region, and further including a substrate, a light-emitting unit, a packaging layer and a dam structure. The light-emitting unit is arranged on a side of the substrate and located within the display region; the packaging layer includes an organic packaging sub-layer covering the light-emitting unit; the dam structure is arranged on the side of the substrate and within the non-display region, the dam structure includes a first dam, and the first dam includes a first metal layer and a first insulating layer that are arranged in a stacked manner.

In some embodiments, the dam structure further includes a second dam adjacent to the first dam, and an overflow groove is formed between the first dam and the second dam;

optionally, the second dam is located on a side of the first dam away from the display region, and a height of the second dam is higher than a height of the first dam;
optionally, the height H3 of the first dam satisfies: 3.5 um≤H3≤5 um;
optionally, the height H4 of the second dam satisfies: 5.5 um≤H4≤8.5 um;
optionally, the second dam includes a second metal layer and a second insulating layer that are arranged in a stacked manner, a thickness of the first metal layer is equal to a thickness of the second metal layer, and a thickness of the second insulating layer is larger than a thickness of the first insulating layer; and
optionally, the display panel further includes a third insulating layer, that is located between the dam structure and the substrate in a direction perpendicular to the substrate, a groove is provided on a side of the third insulating layer away from the substrate, and the overflow groove includes the groove.

In some embodiments, the first insulating layer includes a first organic insulating sub-layer and a first inorganic insulating sub-layer, the second insulating layer includes a second organic insulating sub-layer and a second inorganic insulating sub-layer, the first metal layer, the first organic insulating sub-layer and the first inorganic insulating sub-layer are arranged in a stacked manner, and the second metal layer, the second organic insulating sub-layer and the second inorganic insulating sub-layer are arranged in a stacked manner; and

optionally, a thickness of the second organic insulating sub-layer in the direction perpendicular to the substrate is larger than a thickness of the first organic insulating sub-layer in the direction perpendicular to the substrate.

In a third aspect, embodiments of the present application further provide a display device including the display panel according to any one of the embodiments.

The embodiments of the present application provide the display panel and the display device. The display panel includes the display region and the non-display region, and further includes the substrate, the light-emitting unit, the separating structure, the packaging layer and the dam structure. The light-emitting unit is located on the side of the substrate and within the display region. The separating structure is located on the side of the substrate and within the display region, and the separating structure is provided with the separating opening to accommodate the light-emitting unit, so as to reduce the crosstalk of current carriers in the light-emitting layer and improve the display effect of the display panel. Moreover, the manufacture of light-emitting units does not require using a precision mask plate, so that the development and usage of the precision mask plate can be reduced and the production cost can be reduced. The packaging layer includes an organic packaging sub-layer covering the light-emitting unit; the dam structure is arranged on the side of the substrate and within the non-display region, the dam structure includes a first dam, and the first dam includes a first metal layer, so that the first dam can be formed by stacking the first metal layer and the first insulating layer, so as to increase a thickness of the first dam in the direction perpendicular to the substrate, improve the blocking effect of the dam structure on the packaging material of the organic packaging sub-layer, reduce the risk of moisture and oxygen intrusion caused by the overflow of the packaging material of the organic packaging sub-layer, and improve the reliability of the product.

### BRIEF DESCRIPTION OF THE DRAWINGS

In order to more clearly illustrate the technical solution of the embodiments of the present application, the drawings required to be used in the embodiments of the present application will be briefly introduced below. For those skilled in the art, other drawings can also be obtained according to these drawings without the inventive labor.

FIG. 1 shows a top view of a display panel in a related art according to some embodiments of the present application;

FIG. 2 shows a cross-sectional schematic view of a display panel according to some embodiments of the present application;

FIG. 3 shows another cross-sectional schematic view of a display panel according to some embodiments of the present application;

FIG. 4 shows a cross-sectional schematic view of a display panel according to some other embodiments of the present application;

FIG. 5 shows another cross-sectional schematic view of a display panel according to some other embodiments of the present application;

FIG. 6 shows another cross-sectional schematic view of a display panel according to some other embodiments of the present application;

FIG. 7 shows another cross-sectional schematic view of a display panel according to some other embodiments of the present application;

FIG. 8 shows a cross-sectional schematic view of at region A-A in FIG. 5;

FIG. 9 shows a cross-sectional schematic view of a display panel according to some other embodiments of the present application;

FIG. 10 shows a cross-sectional schematic view of a display panel according to some other embodiments of the present application; and

FIG. 11 shows a cross-sectional schematic view of a display panel according to some other embodiments of the present application.

### REFERENCE NUMERALS

100: display panel; 10: substrate; 20: separating structure; 30: packaging layer; 32: second inorganic packaging sub-layer; 40: dam structure; 41: first dam; 411: first metal layer; 4111: first metal sub-layer; 4112: second metal sub-layer; 412: first insulating layer; 4121: first organic insulating sub-layer; 4122: first inorganic insulating sub-layer; 42: overflow groove; 43: second dam; 431: second metal layer; 4311: third metal sub-layer; 4312: fourth metal sub-layer; 432: second insulating layer 432; 4321: second organic insulating sub-layer; 4322: second inorganic insulating sub-layer; 4323: second sub-layer; 4324: first sub-layer; 44: connecting layer; 441: conductive region; 442: via hole region; 50: third insulating layer; 51: groove; 60: driving circuit layer; 61: third conductive layer; 62: fourth conductive layer; AA: display region; NA: non-display region.

### DETAILED DESCRIPTION

Features and exemplary embodiments in various aspects of the present application will be described in detail below. In order to make the objects, technical solutions and advantages of the present application clearer, the present application will be further described in detail below in conjunction with the drawings and the specific embodiments. It should be understood that the specific embodiments described here are only configured to explain the present application, not to limit the present application. It is apparent to one skilled in the art that the present application can be practiced without some of these specific details. The description of the embodiments below is only to provide a better understanding of the present application by showing examples of the present application.

It shall be noted that, in this context, relational terms such as first and second are merely used to distinguish one entity or operation from another entity or operation, and do not necessarily require or imply any such actual relationship or order between the entities or operations. Further, the term “comprise”, “include” or any other variations thereof is intended to encompass a non-exclusive inclusion, such that a process, method, article, or device including a plurality of elements includes not only these elements but also other elements not listed, or elements that are inherent to such process, method, article or device. Without more limitations, an element that is defined by an expression “comprises . . .”, does not exclude other identical elements in the process, method, article, or device comprising this element.

In a flexible AMOLED display panel, in order to ensure the reliability of the product and prevent the material of the display panel from being corroded by moisture and oxygen, generally, a packaging layer is provided on a surface of the display panel. The packaging layer generally includes an organic packaging sub-layer formed by inkjet printing. Due to the good fluidity of the packaging material formed by the organic packaging sub-layer during a process of inkjet printing, the packaging material may flow outward and overflow to an edge of the packaging layer, which may affect the packaging effect of the packaging layer, increase the risk of moisture and oxygen intrusion, and affect the product reliability of the display panel. Therefore, in order to prevent the packaging material of the organic packaging sub-layer from flowing out and overflowing, a dam structure can be arranged in a non-display region of the display panel to limit the packaging material of the organic packaging sub-layer. Currently, the dam structure as described above can be formed by stacking a pixel-defining layer with a support column used to support a precision mask plate. However, light-emitting units in some display panels do not need to use the precision mask plates, nor do they need to manufacture the above support columns in the display panels, thereby resulting in decrease in a thickness of the dam structure. Therefore, the dam structure is difficult to effectively limit the packaging material of the organic packaging sub-layer, which may increase the risk of moisture and oxygen intrusion at the packaging layer and affect the reliability of the product.

Patents PCT/CN2023/134518, 202311499823.9, 202310707209.0, 202311346196.5, 202310692671.8 and 202311091555.7 recite the relevant content about the separating structure and packaging layer for reference.

Embodiments of the present application provide a display panel, which can be an organic Light Emitting Diode (OLED) display panel or other type of display panel, such as a Micro Light Emitting Diode (Micro LED) display panel or a Quantum Light Emitting Diode (QLED) display panel.

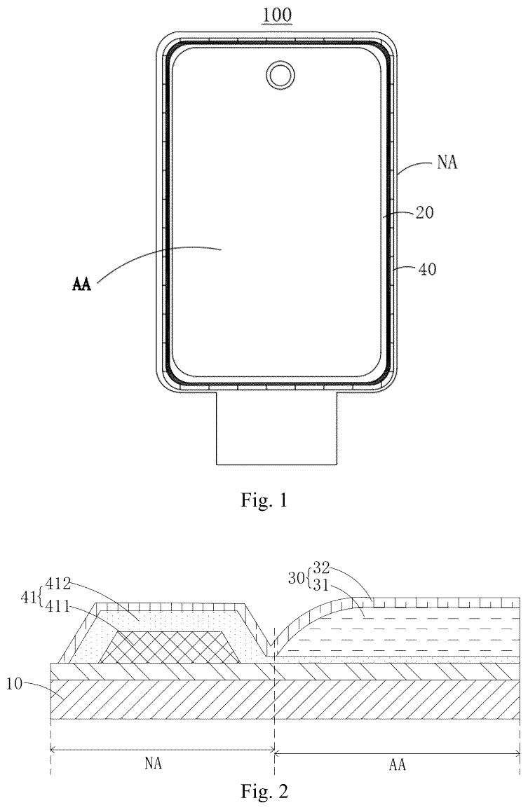

Referring to FIG. 1 and FIG. 2, in an aspect, embodiments of the present application provide a display panel 100 including a display region AA and a non-display region NA, and further including a substrate 10, at least one light-emitting unit, a separating structure 20, a packaging layer 30 and a dam structure 40. The light-emitting unit is arranged on a side of the substrate 10 and located within the display region AA; the separating structure 20 is arranged on the side of the substrate 10 and located within the display region AA, and the separating structure 20 is provided with at least one separating opening to accommodate the light-emitting unit; the packaging layer 30 includes an organic packaging sub-layer 31 covering the light-emitting unit; the dam structure 40 is arranged on the side of the substrate 10 and located within the non-display region NA, the dam structure 40 includes a first dam 41, and the first dam 41 includes a first metal layer 411.

The substrate 10 includes a base, which may be a hard base made of the material such as glass or plastic, or a flexible substrate made of the material such as polyethersulfone (PES), polyacrylate (PAR), polyetherimide (PEI), polyethylene terephthalate (PEN), polyethylene terephthalate (PET), polyphenylene sulfide (PPS), polyarylester, polyimide (PI), polycarbonate (PC) or cellulose acetate (CAP).

The display region AA refers to a region where the image can be displayed, and is provided with sub-pixels. The non-display region NA refers to a region where the image cannot be displayed, and is generally used for wiring, placing a camera, binding a terminal, testing a terminal or the like. For example, the non-display region NA may surround in a circumferential direction of the display region AA, and be an outer border of the display panel 100.

The separating structure 20 can be a structure with a wide top and a narrow bottom, or a structure with a side wall face being dented inward, as long as the evaporated material cannot be continuously deposited on the side wall face of the separating structure 20. Exemplarily, a longitudinal section of the separating structure 20 may be in a shape of inverted trapezoid, X shape, T shape or H shape.

The display panel 100 further includes the light-emitting unit, which is arranged in the separating opening formed and enclosed by the separating structure 20. The light-emitting unit may be formed by stacking a plurality of types of film layer structures. Exemplarily, the light-emitting unit may include a hole injection layer (HIL), a hole transport layer (HTL), a light-emitting layer, an electron injection layer (EIL) and an electron transport layer (ETL) that are arranged in a stacked manner.

It can be understood that the organic packaging sub-layer 31 is arranged on the side of the light-emitting unit away from the substrate 10, which can separate the external moisture, oxygen or the like from entering the interior of the display panel 100. The organic packaging sub-layer 31 includes an organic material. The organic packaging sub-layer 31 may be made of the organic material such as polymer.

In the display panel 100 provided by the embodiments of the present application, the separating structure 20 is located on the side of the substrate 10 and within the display region AA. The separating structure 20 is provided with the separating opening to accommodate the light-emitting unit, so as to reduce the crosstalk of current carriers in the light-emitting layer and improve the display effect of the display panel 100. Moreover, the manufacture of light-emitting units does not require using a precision mask plate, so that the development and usage of the precision mask plate can be reduced and the production cost can be reduced. The packaging layer 30 is located on the side of the separating structure 20 away from the substrate 10. The packaging layer 30 includes an organic packaging sub-layer 31 covering the light-emitting unit. The dam structure 40 is arranged on the side of the substrate 10 and within the non-display region NA, the dam structure 40 includes a first dam 41, and the first dam 41 includes the first metal layer 411, so that the first dam 41 can be formed by the first metal layer 411, so as to increase a thickness of the first dam 41 in the direction perpendicular to the substrate 10, improve the blocking effect of the dam structure 40 on the packaging material of the organic packaging sub-layer 31, reduce the risk of moisture and oxygen intrusion caused by the overflow of the packaging material of the organic packaging sub-layer 31, and improve the reliability of the product.

Optionally, the packaging layer 30 further includes a first inorganic packaging sub-layer, which is located on a side of the separating structure 20 away from the array substrate 10 and between the separating structure 20 and the organic packaging sub-layer 31. The first inorganic packaging sub-layer can protect sub-pixels from being affected by the external environment such as air and moisture, prevent the air and moisture from penetrating into the interior of the display panel 100, and prolong the service life and the stability of a light-emitting structure. The packaging layer 30 can also prevent the impurities and harmful substances from entering the display panel 100, thereby ensuring the performance and quality of the display panel 100.

Optionally, the first inorganic packaging sub-layer includes an inorganic material. Exemplarily, the first inorganic packaging sub-layer can be made of the material such as silicon oxide, silicon nitride or silicon oxynitride, which can provide good mechanical support and packaging protection to prevent the display panel 100 from being affected by the environment. In addition, the first inorganic packaging sub-layer can effectively separate the harmful substances such as external moisture and oxygen from entering the interior of the display panel 100, thereby prolonging the service life and improving the stability of the display panel 100.

Optionally, a thickness of the organic packaging sub-layer 31 is larger than that of the first inorganic packaging sub-layer, and the organic packaging sub-layer has stronger flexibility, so that the organic packaging sub-layer can better adapt to the bending and curvature of the display panel 100. Moreover, the organic material can also buffer the external force.

Referring to FIG. 2, optionally, the packaging layer 30 further includes a second inorganic packaging sub-layer 32. The second inorganic packaging sub-layer 32 can further protect sub-pixels from being affected by the external environmental such as air and moisture, prevent the air and moisture from penetrating into the interior of the display panel 100, prolong the service life and improve the stability of the light-emitting structure. The second inorganic packaging sub-layer 32 can also prevent the impurities and harmful substances from entering the display panel 100, thereby ensuring the performance and quality of the display panel 100. The organic packaging sub-layer 31 can be arranged between the first inorganic packaging sub-layer and the second inorganic packaging sub-layer 32. Therefore, the first inorganic packaging sub-layer and the second inorganic packaging sub-layer 32 can be raised to surround the organic packaging sub-layer 31, thereby preventing the packaging material of the organic packaging sub-layer 31 from flowing out.

Referring to FIG. 2, in some embodiments, the first dam 41 further includes a first insulating layer 412 stacked with the first metal layer 411, thereby further increasing the thickness of the first dam 41 in the direction perpendicular to the substrate 10.

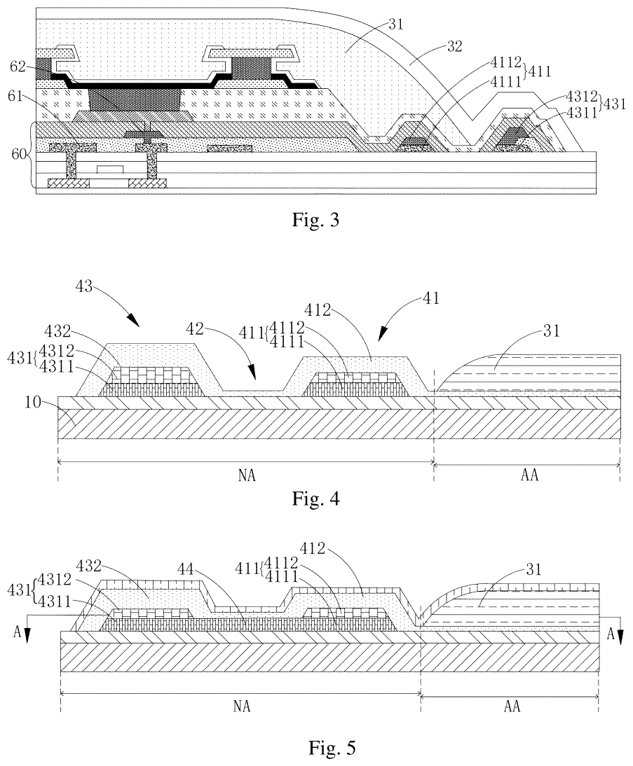

Referring to FIG. 3, optionally, the display panel 100 includes a driving circuit layer 60 arranged on the side of the substrate 10, the driving circuit layer 60 includes a first conductive layer, a second conductive layer, a third conductive layer 61 and a fourth conductive layer 62 arranged in a stacked manner, and the first metal layer 411 is formed with the same material and at a same layer as at least one of the first conductive layer, the second conductive layer, the third conductive layer 61 or the fourth conductive layer 62. Therefore, the first metal layer 411 can be manufactured by performing the same process as at least one of the first conductive layer, second conductive layer, third conductive layer 61 or fourth conductive layer 62, or the first metal layer 411 can be formed by extending from at least one of the first conductive layer, second conductive layer, third conductive layer 61 or fourth conductive layer 62 towards the non-display region NA, thereby simplifying the process steps and reducing the production cost.

Referring to FIG. 4, in some embodiments, the dam structure 40 further includes a second dam 43 adjacent to the first dam 41, and an overflow groove 42 is formed between the first dam 41 and the second dam 43, so that the packaging material of the organic packaging sub-layer 31 can be limited by the first dam 41 and the second dam 43, sequentially, so as to more effectively block the packaging material of the organic packaging sub-layer 31 from flowing outwards and overflowing. When the packaging material as described above overflows the first dam 41, it can flow into the overflow groove 42 and be blocked by the second dam 43, so as to limit the organic packaging sub-layer 31 within the dam structure 40 and prevent the packaging material of the organic packaging sub-layer 31 from flowing out and overflowing.

Optionally, the second dam 43 is located on a side of the first dam 41 away from the display region AA, and a height H4 of the second dam 43 is higher than a height H3 of the first dam 41, so as to further improve the limiting effect of the dam structure 40 on the organic packaging sub-layer 31.

Referring to FIG. 1, optionally, the dam structure 40 is arranged to surround the display region AA, so that the organic packaging sub-layer 31 can be limited within the dam structure 40 in the circumferential direction of the display region AA, so as to prevent the packaging material of the organic packaging sub-layer 31 from flowing out and overflowing.

Referring to FIG. 4, in some embodiments, the second dam 43 includes a second metal layer 431 and a second insulating layer 432 stacked with the second metal layer 431, so as to increase a thickness of the second dam 43 in the direction perpendicular to the substrate 10 and improve the blocking effect of the dam structure 40 on the packaging material of the organic packaging sub-layer 31.

Referring to FIG. 3, optionally, the second metal layer 431 is formed with the same material and at a same layer as at least one of the first conductive layer, second conductive layer, third conductive layer 61 or fourth conductive layer 62. Therefore, the second metal layer 431 can be manufactured by performing the same process as at least one of the first conductive layer, second conductive layer, third conductive layer 61 or fourth conductive layer 62, or the second metal layer 431 can be formed by extending from at least one of the first conductive layer, second conductive layer, third conductive layer 61 or fourth conductive layer 62 towards the non-display region NA, thereby simplifying the process steps and reducing the production cost.

Referring to FIG. 4, optionally, the first metal layer 411 is spaced apart from the second metal layer 431, so that the first metal layer 411 and the second metal layer 431 can be insulated from each other. When the first metal layer 411 and the second metal layer 431 are connected to different voltages, respectively, the first metal layer 411 and the second metal layer 431 are arranged to be insulated from each other, which can avoid the interference between the voltage carried by the first metal layer 411 and the voltage carried by the second metal layer 431.

Optionally, the first metal layer 411 or the second metal layer 431 can be connected to any one of the initialization voltage, the reference voltage or the clock signal of the display panel 100. Of course, the first metal layer or the second metal layer can also be connected to the positive power supply voltage or the negative power supply voltage, and the embodiment does not limited to this.

Referring to FIG. 5 to FIG. 7, optionally, the first metal layer 411 is conducted with the second metal layer 431. When the first metal layer 411 and the second metal layer 431 are connected to the same voltage, simultaneously, the first metal layer 411 and the second metal layer 431 are conducted with each other, which can improve the resistance conductivity.

Optionally, the first metal layer 411 includes a first metal sub-layer 4111 and a second metal sub-layer 4112 sequentially stacked in a direction away from the substrate 10, so as to increase a thickness of the first metal layer 411 in the direction perpendicular to the substrate 10, and further increase a thickness of the dam structure 40 in the direction perpendicular to the substrate 10.

Referring to FIG. 3, the first metal sub-layer 4111 and the third conductive layer 61 are arranged in the same layer and formed with the same material, and the second metal sub-layer 4112 and the fourth conductive layer 62 are arranged in the same layer and formed with the same material.

It can be understood that, in the driving circuit layer 60, each of a thickness of the third conductive layer 61 and a thickness of the fourth conductive layer 62 is larger than each of a thickness of the first conductive layer and a thickness of the second conductive layer. Therefore, in this embodiment, the first metal sub-layer 4111 and the third conductive layer 61 are arranged in the same layer and formed with the same material, and the second metal sub-layer 4112 and the fourth conductive layer 62 are arranged in the same layer and formed with the same material. Compared with a case that the first metal sub-layer 4111 and the first conductive layer are arranged in the same layer and formed with the same material, and the second metal sub-layer 4112 and the second conductive layer are arranged in the same layer and formed with the same material, this embodiment can achieve that the thickness of the first metal sub-layer 4111 and the thickness of the second metal sub-layer 4112 increase, and the thickness of the dam structure 40 in the direction perpendicular to the substrate 10 further increases.

Referring to FIG. 4, optionally, the second metal layer 431 includes a third metal sub-layer 4311 and a fourth metal sub-layer 4312 sequentially stacked in the direction away from the substrate 10, so as to further increase a thickness of the second dam 43 in the direction perpendicular to the substrate 10.

It can be understood that when the first metal layer 411 includes the first metal sub-layer 4111 and the second metal sub-layer 4112, and the second metal layer 431 includes the third metal sub-layer 4311 and the fourth metal sub-layer 4312, the first metal layer 411 and the second metal layer 431 are conducted with each other, which mean that the first metal sub-layer 4111 and the third metal sub-layer 4311 are conducted with each other, or the second metal sub-layer 4112 and the fourth metal sub-layer 4312 are conducted with each other, or the first metal sub-layer 4111 and the third metal sub-layer 4311 are conducted with each other, while the second metal sub-layer 4112 and the fourth metal sub-layer 4312 are also conducted with each other.

Referring to FIG. 5, in some embodiments, the first metal sub-layer 4111 and the third metal sub-layer 4311 are arranged in the same layer and conducted with each other. Therefore, when the first metal layer 411 and the second metal layer 431 are connected to the same voltage, simultaneously, the resistance conductivity between the first metal layer 411 and the second metal layer 431 can be improved.

Referring to FIG. 3, optionally, the first metal sub-layer 4111, the third metal sub-layer 4311 and the third conductive layer 61 are arranged in the same layer and formed with the same material. Therefore, the first metal sub-layer 4111, the third metal sub-layer 4311 and the third conductive layer 61 can be manufactured and formed by performing the same process, or the first metal sub-layer 4111 and the third metal sub-layer 4311 can be formed by extending from the third conductive layer 61 towards the non-display region NA, so as to simplify the process steps and reduce the production cost.

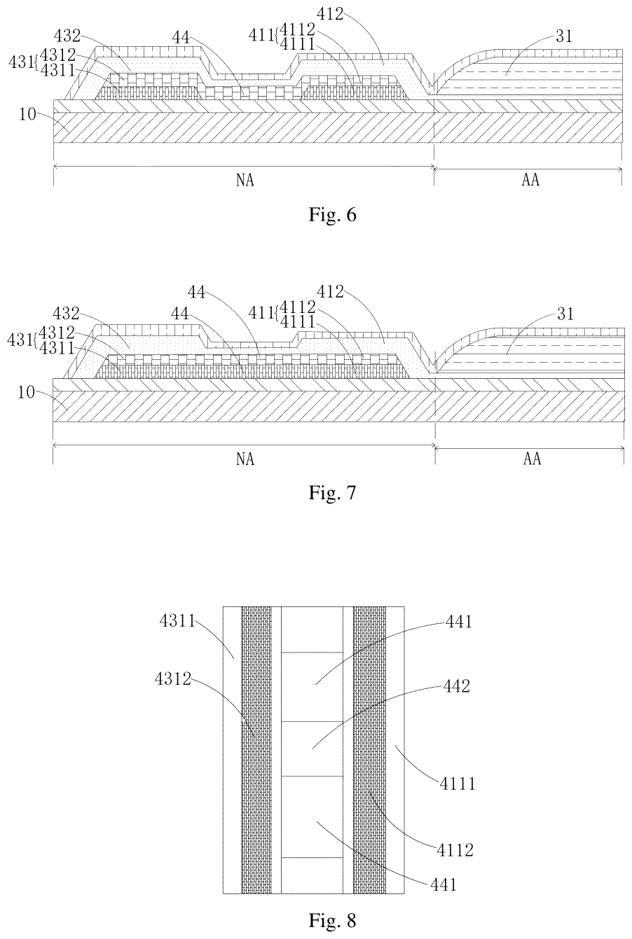

Referring to FIG. 6, in some embodiments, the second metal sub-layer 4112 and the fourth metal sub-layer 4312 are arranged in the same layer and conducted with each other. Therefore, when the first metal layer 411 and the second metal layer 431 are connected to the same voltage, simultaneously, the resistance conductivity between the first metal layer 411 and the second metal layer 431 can be improved.

Referring to FIG. 3, optionally, the second metal sub-layer 4112, the fourth metal sub-layer 4312 and the fourth conductive layer 62 are arranged in the same layer and formed with the same material. Therefore, the second metal sub-layer 4112, the fourth metal sub-layer 4312 and the fourth conductive layer 62 can be manufactured and formed by performing the same process, or the second metal sub-layer 4112 and the fourth metal sub-layer 4312 can be formed by extending from the fourth conductive layer 62 towards the non-display region NA, so as to simplify the process steps and reduce the production cost.

Referring to FIG. 5 to FIG. 7, in some embodiments, the dam structure 40 further includes a connecting layer 44, which is arranged between the first dam 41 and the second dam 43 and conducts the first metal layer 411 with the second metal layer 431. Compared with a wire or other conductive manner used to connect the first metal layer 411 with the second metal layer 431, the connecting layer can improve the resistance conductivity between the first metal layer 411 and the second metal layer 431.

The connecting layer 44 located between the first metal sub-layer 4111 and the third metal sub-layer 4311 may be arranged in the same layer and formed with the same material as the first metal sub-layer 4111 and the third metal sub-layer 4311, and the connecting layer 44 located between the second metal sub-layer 4112 and the fourth metal sub-layer 4312 may be arranged in the same layer and formed with the same material as the second metal sub-layer 4112 and the fourth metal sub-layer 4312, so as to further simplify the process steps.

Referring to FIG. 8, optionally, the connecting layer 44 includes a conductive region 441 and a via hole region 442, the conductive region 441 conducts the first metal layer 411 with the second metal layer 431, the via hole region 442 is provided with a via hole in the direction perpendicular to the substrate 10, and the overflow groove 42 includes the via hole.

The conductive region 441 is used to conduct the first metal layer 411 with the second metal layer 431. The via hole region 442 is provided with a via hole in the direction perpendicular to the substrate 10, and the overflow groove 42 includes the via hole, so as to increase the depth of the overflow groove 42 in the direction perpendicular to the substrate 10, increase the volume of the overflow groove 42, allow the overflow groove 42 to accommodate more packaging materials of the organic packaging sub-layer 31, and avoid the packaging materials from flowing out and overflowing.

Optionally, there are a plurality of conductive regions 441 and a plurality of via hole regions 442, and the plurality of conductive regions 441 and the plurality of via hole regions 442 are arranged alternately in an extending direction of an edge of the display region AA, so as to increase a volume of the overflow groove 42 by reasonably setting the number and the position of conductive region 441 and the via hole regions 442 in the connecting layer, while ensure the resistance conductivity between the first metal layer 411 and the second metal sub-layer 4112.

In some embodiments, when both the first metal layer 411 and the second metal layer 431 are connected to a non-power supply voltage, a range of a ratio of a length L1 of the conductive region 441 in the extending direction of the edge of the display region AA to a length L2 of the via hole region 442 in the extending direction of the edge of the display region AA satisfies: 0:10<L1: L2<5:5. Therefore, when both the first metal layer 411 and the second metal layer 431 are connected to the non-power supply voltage, the length L1 of the conductive region 441 and the length L2 of the via hole region 442 can be set reasonably, so that a range of the via hole region 442 can increase, while the resistance conductivity between the first metal layer 411 and the second metal layer 431 can be ensured. Thus, a size of the via hole within via hole region 442 can increase, and the volume of the overflow groove 42 can further increase.

Optionally, when both the first metal layer 411 and the second metal layer 431 are connected to the non-power supply voltage, the ratio of the length L1 of the conductive region 441 in the extending direction of the edge of the display region AA to the length L2 of the via hole region 442 in the extending direction of the edge of the display region AA is 1:9, so as to maximize the range of the via hole region while ensuring the resistance conductivity between the first metal layer 411 and the second metal layer 431.

In some embodiments, when both the first metal layer 411 and the second metal layer 431 are connected to a power supply voltage, the range of the ratio of the length L1 of the conductive region 441 in the extending direction of the edge of the display region AA to the length L2 of the via hole region 442 in the extending direction of the edge of the display region AA satisfies: 5:5≤L1: L2≤9:1. Therefore, when both the first metal layer 411 and the second metal layer 431 are connected to the power supply voltage, the length L1 of the conductive region 441 and the length L2 of the via hole region 442 can be set reasonably, so that the range of the via hole region can increase, while the resistance conductivity between the first metal layer 411 and the second metal layer 431 can be ensured. Thus, the size of the via hole within via hole region can increase, and the volume of the overflow groove 42 can further increase.

Optionally, when both the first metal layer 411 and the second metal layer 431 are connected to the power supply voltage, the range of the ratio of the length L1 of the conductive region 441 in the extending direction of the edge of the display region AA to the length L2 of the via hole region 442 in the extending direction of the edge of the display region AA is: 5:5, so as to maximize the range of the via hole region while ensuring the resistance conductivity between the first metal layer 411 and the second metal layer 431.

It can be understood that in the display panel 100, a value of the power supply voltage is larger than a value of the non-power supply voltage. Therefore, compared with a case that both the first metal layer and the second metal layer are connected to the non-power supply voltage, when both the first metal layer 411 and the second metal layer 431 are connected to the power supply voltage, the length L1 of the conductive region 441 can be correspondingly increase, and the length L2 of the via hole region 442 can be shortened, thereby improving the resistance conductivity between the first metal layer 411 and the second metal layer 431.

Referring to FIG. 3, in some embodiments, the first insulating layer 412 includes a first organic insulating sub-layer 4121 and a first inorganic insulating sub-layer 4122, and the first metal layer 411, the first organic insulating sub-layer 4121 and the first inorganic insulating sub-layer 4122 are arranged in a stacked manner; the second insulating layer 432 includes a second organic insulating sub-layer 4321 and a second inorganic insulating sub-layer 4322, and the second metal layer 431, the second organic insulating sub-layer 4321 and the second inorganic insulating sub-layer 4322 are arranged in a stacked manner, so as to increase the thickness of the first insulating layer 412 in the direction perpendicular to the substrate 10 and the thickness of the second insulating layer 432 in the direction perpendicular to the substrate 10, and further increase the thickness of the dam structure 40 in the direction perpendicular to the substrate 10.

It can be understood that the first insulating layer 412 and the second insulating layer 432 are formed by stacking the organic layers and stacking the inorganic layers, respectively, which can buffer the external force, and provide the good mechanical support performance to the dam structure 40.

Referring to FIG. 10, in some embodiments, the display panel 100 further includes a first planarization layer 70 located within the display region AA. The first planarization layer 70, the first organic insulating sub-layer 4121 and at least a portion of the second organic insulating sub-layer 4321 are arranged in the same layer and formed with the same material. Therefore, the first organic insulating sub-layer 4121 and at least a portion of the second organic insulating sub-layer 4321 can be manufactured by performing the same process as the first planarization layer 70, so as to simplify the process steps and reduce the production cost.

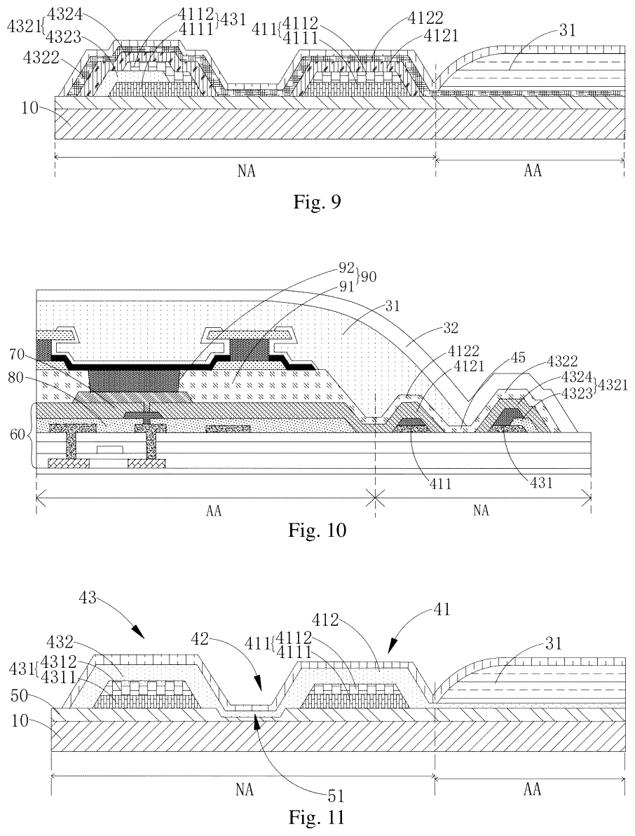

Referring to FIG. 9 and FIG. 10, optionally, the display panel 100 further includes a second planarization layer 80 located within the display region AA, the second organic insulating sub-layer 4321 includes a first sub-layer 4324 and a second sub-layer 4323, the first sub-layer 4324 and the first planarization layer 70 are arranged in the same layer and formed with the same material, and the second sub-layer 4323 and the second planarization layer 80 are arranged in the same layer and formed with the same material.

In this embodiment, the second organic insulating sub-layer 4321 includes a first sub-layer 4324 and a second sub-layer 4323, and the first sub-layer 4324 and the first planarization layer 70 are arranged in the same layer and formed with the same material. Therefore, a thickness of the second organic insulating sub-layer 4321 is larger than a thickness of the first organic insulating sub-layer 4121, that is, the thickness of the second dam 43 may be larger than the thickness of the first dam 41, so as to further improve the limiting effect of the dam structure 40 on the organic packaging sub-layer 31. In addition, the first sub-layer 4324 can be manufactured by performing the same process as the first planarization layer 70, and the second sub-layer 4323 can be manufactured by performing the same process as the second flattened layer 80, so as to simplify the process steps, improve the production efficiency, and reduce the production cost.

Optionally, the second sub-layer 4323 extends from one end of the third metal sub-layer 4311 to cover one portion of the third metal sub-layer 4311, the fourth metal sub-layer 4312 covers the other portion of the third metal sub-layer 4311, and the first sub-layer 4324 covers the second sub-layer 4323 and the second metal layer 431, so as to increase the thickness of the second organic insulating sub-layer 4321 by reasonably setting the positions of the first sub-layer 4324, the second sub-layer 4323, the third metal sub-layer 4311 and the fourth metal sub-layer 4312, while ensure the conductivity between the third metal sub-layer 4311 and the fourth metal sub-layer 4312.

Optionally, the first organic insulating sub-layer 4121 covers the first metal layer 411, so as to protect the first metal layer 411 and ensure the relative insulation of the first metal layer 411.

Referring to FIG. 10, in some embodiments, the display panel 100 further includes a pixel-defining layer 90 located within the display region AA. The pixel-defining layer 90 includes a pixel-defining portion 91 and a pixel opening 92 formed and enclosed by the pixel-defining portion 91, the pixel opening 92 is configured to arrange the light-emitting unit, the separating structure 20 is arranged on a side of the pixel-defining portion 91 away from the substrate 10, and the first inorganic insulating sub-layer 4122, the second inorganic insulating sub-layer 4322 and the pixel-defining layer 90 are arranged in the same layer and formed with the same material.

In this embodiment, the first inorganic insulating sub-layer 4122, the second inorganic insulating sub-layer 4322 and the pixel-defining layer 90 are arranged in the same layer and formed with the same material. Therefore, the first inorganic insulating sub-layer 4122 and the second inorganic insulating sub-layer 4322 manufactured by performing the same process as the pixel-defining layer 90, so as to reduce the process steps and reduce the production cost. In addition, in this embodiment, the first inorganic insulating sub-layer 4122, the second inorganic insulating sub-layer 4322 and the pixel-defining layer 90 are arranged in the same layer and formed with the same material. That is, the pixel-defining layer 90 is manufactured by the inorganic material, which can reduce the thickness of the pixel-defining layer 90, reduce the overall thickness of the display panel 100, allow the display panel 100 lighter and thinner, while effectively separate the moisture and oxygen to ensure the packaging effect on the individual pixels.

It can be understood that, in this embodiment, since the pixel-defining layer 90 is manufactured by the relatively light and thin inorganic material, the first dam 41 in the dam structure 40 is formed by stacking the first metal layer 411 with the first insulating layer 412. The first insulating layer 412 includes the first organic insulating sub-layer 4121 and the first inorganic insulating sub-layer 4122, so that the first inorganic insulating sub-layer 4122 can be compensated by the first metal layer 411 and the organic insulating sub-layer 4121, and it can ensure that the dam 41 has the enough thickness to limit the packaging material in the organic packaging sub-layer 31.

Referring to FIG. 10, optionally, the display panel 411 further includes a third inorganic insulating sub-layer 45 arranged between the first dam 41 and the second dam 43. The third inorganic insulating sub-layer 45, the first inorganic insulating sub-layer 4122, the second inorganic insulating sub-layer 4322 and the pixel-defining layer 90 are arranged in the same layer and formed with the same material. The overflow groove 42 is located on a side of the third inorganic insulating sub-layer 45 away from the substrate 10.

Optionally, the display panel 100 further includes a third insulating layer, which is located between the dam structure 40 and the substrate 10 in the direction perpendicular to the substrate 10. The third inorganic insulating sub-layer 45 is attached to a side of the third insulating layer 50 away from the substrate 10 when the first metal layer 411 is spaced apart from the second metal layer 431, and the third inorganic insulating sub-layer 45 is attached to a side of the connecting layer 44 away from the substrate 10 when the connecting layer 44 conducts the first metal layer 411 with the second metal layer 431, so that a depth of the overflow groove 42 in the direction perpendicular to the substrate 10 can be reasonably adjusted to ensure the blocking effect of the dam structure 40.

Referring to FIG. 10, in some embodiments, both an orthographic projection of the first metal layer 411 on the substrate 10 and an orthographic projection of the first organic insulating sub-layer 4121 on the substrate 10 are located within an orthographic projection of the first inorganic insulating sub-layer 4122 on the substrate 10, and both an orthographic projection of the second metal layer 431 on the substrate 10 and an orthographic projection of the second organic insulating sub-layer 4321 on the substrate 10 are located within an orthographic projection of the second inorganic insulating sub-layer 4322 on the substrate 10. Therefore, the first inorganic insulating sub-layer 4122 can protect the first metal layer 411 and the first organic insulating sub-layer 4121, and the second inorganic insulating sub-layer 4322 can protect the second metal layer 431 and the second organic insulating sub-layer 4321.

Referring to FIG. 3 and FIG. 10, optionally, the packaging layer 30 further includes a second inorganic packaging sub-layer 32 covering the organic packaging sub-layer 31, the second inorganic packaging sub-layer 32 extends to the non-display region NA and covers the dam structure 40, and an orthographic projection of a portion of the second inorganic packaging sub-layer 32 within the non-display region NA on the substrate 10 overlaps with both an orthographic projection of the first inorganic insulating sub-layer 4122 on the substrate 10 and an orthographic projection of the second inorganic insulating sub-layer on the substrate 10, so as to protect the dam structure 40 by the second inorganic packaging sub-layer 32, and further prevent the air and moisture from penetrating into the interior of the display panel 100.

Referring to FIG. 11, in a second aspect, embodiments of the present application further provide a display panel 100 including a display region AA and a non-display region NA, and further including a substrate 10, a light-emitting unit, a packaging layer 30 and a dam structure 40. The light-emitting unit is arranged on a side of the substrate 10 and located within the display region AA; the packaging layer 30 includes an organic packaging sub-layer 31 covering the light-emitting unit; the dam structure 40 is arranged on the side of the substrate 10 and within the non-display region NA, the dam structure 40 includes a first dam 41, and the first dam 41 includes a first metal layer 411 and a first insulating layer 412 that are arranged in a stacked manner.

In the display panel 100 according to the embodiments of the present application, the dam structure 40 includes the first dam 41, and the first dam 41 includes the first metal layer 411 and the first insulating layer 412 that are arranged in a stacked manner, so that the first dam 41 is formed by stacking the first metal layer 411 and the first insulating layer 412, which can increase the thickness of the first dam 41 in the direction perpendicular to the substrate 10, improve the blocking effect of the dam structure 40 on the packaging material of the organic packaging sub-layer 31, reduce the risk of moisture and oxygen intrusion caused by the overflow of the packaging material of the organic packaging sub-layer 31, and improve the reliability of the product.

In some embodiments, the dam structure 40 further includes a second dam 43 adjacent to the first dam 41, and an overflow groove 42 is formed between the first dam 41 and the second dam 43, so that the packaging material of the organic packaging sub-layer 31 can be limited by the first dam 41 and the second dam 43, sequentially, so as to more effectively block the packaging material of the organic packaging sub-layer 31 from flowing outwards and overflowing. When the packaging material as described above overflows the first dam 41, it can flow into the overflow groove 42 and be blocked by the second dam 43, so as to limit the organic packaging sub-layer 31 within the dam structure 40 and prevent the packaging material of the organic packaging sub-layer 31 from flowing out and overflowing.

Optionally, the second dam 43 is located on a side of the first dam 41 away from the display region AA, and a height of the second dam 43 is higher than a height of the first dam 41, so as to further improve the limiting effect of the dam structure 40 on the organic packaging sub-layer 31.

Optionally, the height H3 of the first dam 41 satisfies: 3.5 um≤H335 um, so as to reasonably set the height of the first dam 41.

Optionally, the height H4 of the second dam satisfies: 5.5 um≤H4≤8.5 um, so as to reasonably set the height of the second dam 43.

Optionally, the second dam 43 includes a second metal layer 431 and a second insulating layer 432 that are arranged in a stacked manner, a thickness of the first metal layer 411 is equal to a thickness of the second metal layer 431, and a thickness of the second insulating layer 432 is larger than a thickness of the first insulating layer 412.

It can be understood that, in the display panel 100, the first metal layer 411 and the second metal layer 431 can be manufactured and formed by means of a PVD sputtering process. Therefore, in this embodiment, the thickness of the first metal layer 411 is set to be equal to the thickness of the second metal layer 431, so that the process difficulty of manufacturing the first metal layer 411 can be reduced. In addition, the thickness of the second insulating layer 432 is set to be larger than the thickness of the first insulating layer 412, so that the height of the dam structure 40 can gradually increase in a direction away from the display region AA, thereby ensuring the limiting effect on the packaging material of the organic packaging sub-layer 31.

As shown in FIG. 11, optionally, the display panel 100 further includes a third insulating layer 50, that is located between the dam structure 40 and the substrate 10 in a direction perpendicular to the substrate 10, a groove 51 is provided on a side of the third insulating layer 50 away from the substrate 10, and the overflow groove 42 includes the groove 51, which can increase the depth of the overflow groove 42 in the direction perpendicular to the substrate 10, so that the overflow groove 42 can accommodate more packaging materials of the organic packaging sub-layer 31, and avoid the packaging materials from flowing out and overflowing.

Optionally, the third insulating layer 50 can also serve as an insulating layer manufactured by the inorganic material within the display region AA of the display panel 100. The third insulating layer 50 includes but is not limited to at least one of a buffer sub-layer, a gate insulating layer, a capacitive insulating sub-layer or the interlayer insulating sub-layer. Thus, there is no need to separately process the third insulating layer 50 or the above-mentioned insulating layer within the display region AA, so as to simplify the process of manufacturing the display panel 100.

In some embodiments, the first insulating layer 412 includes a first organic insulating sub-layer and a first inorganic insulating sub-layer, the second insulating layer 432 includes a second organic insulating sub-layer and a second inorganic insulating sub-layer, the first metal layer 411, the first organic insulating sub-layer and the first inorganic insulating sub-layer are arranged in a stacked manner, and the second metal layer 431, the second organic insulating sub-layer and the second inorganic insulating sub-layer are arranged in a stacked manner, so as to increase the thickness of the first insulating layer 412 in the direction perpendicular to the substrate 10 and the thickness of the second insulating layer 432 in the direction perpendicular to the substrate 10, further increase the thickness of the dam structure 40 in the direction perpendicular to the substrate 10, improve the blocking effect of the dam structure 40 on the packaging material of the organic packaging sub-layer 31, reduce the risk of moisture and oxygen intrusion caused by the overflow of the packaging material of the organic packaging sub-layer 31, and improve the reliability of the product.

Optionally, a thickness of the second organic insulating sub-layer in the direction perpendicular to the substrate 10 is larger than a thickness of the first organic insulating sub-layer in the direction perpendicular to the substrate 10, so as to increase the height of the second dam 43 and improve the limiting effect of the dam structure 40 on the packaging material of the organic packaging sub-layer 31.

Optionally, the first organic insulating sub-layer and the second organic insulating sub-layer can be manufactured by applying the technology of a multi-grayscale light cover. Therefore, there can be a thickness difference between the first organic insulating sub-layer and the second organic insulating sub-layer. In addition, the first organic insulating sub-layer and the second organic insulating sub-layer can be formed through a single exposure, thereby reducing the production cost.

In a third aspect, embodiments of the present application provide a display device including the display panel 100 according to any one of the embodiments. The display device provided by the embodiments of the present application has the technical effect of the display panel 100 according to any one of the embodiments, and explanations of the same or corresponding structures and terms as the above embodiments will not be repeated here.

The display device may be any device with a display function, which may be a mobile device such as a mobile phone, a tablet, a laptop, a handheld computer, a vehicle-bound electronic device, a wearable device, an ultra-mobile personal computer (UMPC), a netbook or a personal digital assistant (PDA), or a non-mobile device such as a personal computer (PC), a television (TV), an ATM or a self-service machine.

The contents as described above are merely the specific embodiments of the present application. Those skilled in the art can clearly understand that, for the convenience and conciseness of the description, the specific working processes of the system, module and unit described above can refer to the corresponding processes in the aforementioned method embodiments, and will not be repeated here. It should be understood that the scope of the present application is not limited to this. Within the scope of the technology disclosed in the present application, any skilled in the art can easily think of various equivalent modifications or replacements, which should be covered within the scope of the present application.

What is claimed is:

1. A display panel, comprising a display region and a non-display region, and further comprising:
a substrate;
at least one light-emitting unit, arranged on a side of the substrate and located within the display region;
a separating structure, arranged on the side of the substrate and located within the display region, and the separating structure being provided with at least one separating opening to accommodate the light-emitting unit;
a packaging layer, comprising an organic packaging sub-layer covering the light-emitting unit; and
a dam structure, arranged on the side of the substrate and located within the non-display region, and comprising a first dam provided with a first metal layer.

2. The display panel according to claim 1, wherein the first dam further comprises a first insulating layer stacked with the first metal layer;
the display panel comprises a driving circuit layer arranged on the side of the substrate, the driving circuit layer comprises a first conductive layer, a second conductive layer, a third conductive layer and a fourth conductive layer arranged in a stacked manner, and the first metal layer is formed with the same material and at a same layer as at least one of the first conductive layer, the second conductive layer, the third conductive layer or the fourth conductive layer.

3. The display panel according to claim 2, wherein the dam structure further comprises a second dam adjacent to the first dam, and an overflow groove formed between the first dam and the second dam.

4. The display panel according to claim 2, wherein the second dam is located on a side of the first dam away from the display region, and a height of the second dam is higher than a height of the first dam; and
the dam structure is arranged to surround the display region.

5. The display panel according to claim 3, wherein
the second dam comprises a second metal layer and a second insulating layer stacked with the second metal layer; and
the second metal layer is formed with the same material and at a same layer as at least one of the first conductive layer, the second conductive layer, the third conductive layer or the fourth conductive layer.

6. The display panel according to claim 5, wherein the first metal layer is spaced apart from the second metal layer; and the first metal layer is conducted with the second metal layer.

7. The display panel according to claim 5, wherein the first metal layer comprises a first metal sub-layer and a second metal sub-layer sequentially stacked in a direction away from the substrate, the first metal sub-layer and the third conductive layer are arranged in the same layer and formed with the same material, and the second metal sub-layer and the fourth conductive layer are arranged in the same layer and formed with the same material; and
the second metal layer comprises a third metal sub-layer and a fourth metal sub-layer sequentially stacked in a direction away from the substrate.

8. The display panel according to claim 5, wherein the first metal sub-layer and the third metal sub-layer are arranged in the same layer and conducted with each other.

9. The display panel according to claim 5, wherein the second metal sub-layer and the fourth metal sub-layer are arranged in the same layer and conducted with each other.

10. The display panel according to claim 5, wherein the dam structure further comprises a connecting layer, and the connecting layer is arranged between the first dam and the second dam and conducts the first metal layer with the second metal layer; and
the connecting layer comprises a conductive region and a via hole region, the conductive region conducts the first metal layer and the second metal layer, the via hole region is provided with a via hole in a direction perpendicular to the substrate, and the overflow groove comprises the via hole.

11. The display panel according to claim 10, wherein the connecting layer comprises a plurality of conductive regions and a plurality of via hole regions, and the plurality of conductive regions and the plurality of via hole regions are arranged alternately in an extending direction of an edge of the display region.

12. The display panel according to claim 10, wherein the first insulating layer comprises a first organic insulating sub-layer and a first inorganic insulating sub-layer,
the first metal layer, the first organic insulating sub-layer and the first inorganic insulating sub-layer are arranged in a stacked manner; the second insulating layer comprises a second organic insulating sub-layer and a second inorganic insulating sub-layer, and
the second metal layer, the second organic insulating sub-layer and the second inorganic insulating sub-layer are arranged in a stacked manner.

13. The display panel according to claim 12, further comprising a first planarization layer located within the display region, wherein the first planarization layer, the first organic insulating sub-layer and at least a portion of the second organic insulating sub-layer are arranged in the same layer and formed with the same material.

14. The display panel according to claim 13, wherein the display panel further comprises a second planarization layer located within the display region, the second organic insulating sub-layer comprises a first sub-layer and a second sub-layer, the first sub-layer and the first planarization layer are arranged in the same layer and formed with the same material, and the second sub-layer and the second planarization layer are arranged in the same layer and formed with the same material.

15. The display panel according to claim 14, wherein the second sub-layer extends from one end of the third metal sub-layer to cover one portion of the third metal sub-layer, the fourth metal sub-layer covers the other portion of the third metal sub-layer, and the first sub-layer covers the second sub-layer and the second metal layer; and
the first organic insulating sub-layer covers the first metal layer.

16. The display panel according to claim 12, further comprising a pixel-defining layer located within the display region, wherein the pixel-defining layer comprises a pixel-defining portion and a pixel opening formed and enclosed by the pixel-defining portion, the pixel opening is configured to arrange the light-emitting unit, the separating structure is arranged on a side of the pixel-defining portion away from the substrate, and the first inorganic insulating sub-layer, the second inorganic insulating sub-layer and the pixel-defining layer are arranged in the same layer and formed with the same material.

17. The display panel according to claim 12, further comprising a third inorganic insulating sub-layer arranged between the first dam and the second dam, wherein the third inorganic insulating sub-layer, the first inorganic insulating sub-layer, the second inorganic insulating sub-layer and the pixel-defining layer are arranged in the same layer and formed with the same material, and the overflow groove is located on a side of the third inorganic insulating sub-layer away from the substrate.

18. The display panel according to claim 12, further comprising a third insulating layer, wherein the third insulating layer is located between the dam structure and the substrate in the direction perpendicular to the substrate,
the third inorganic insulating sub-layer is attached to a side of the third insulating layer away from the substrate when the first metal layer is spaced apart from the second metal layer, and
the third inorganic insulating sub-layer is attached to a side of the connecting layer away from the substrate when the connecting layer conducts the first metal layer with the second metal layer.

19. The display panel according to claim 12, wherein both an orthographic projection of the first metal layer on the substrate and an orthographic projection of the first organic insulating sub-layer on the substrate are located within an orthographic projection of the first inorganic insulating sub-layer on the substrate, and
both an orthographic projection of the second metal layer on the substrate and an orthographic projection of the second organic insulating sub-layer on the substrate are located within an orthographic projection of the second inorganic insulating sub-layer on the substrate.

20. The display panel according to claim 12, wherein the packaging layer further comprises a second inorganic packaging sub-layer covering the organic packaging sub-layer, the second inorganic packaging sub-layer extends to the non-display region and covers the dam structure, and
an orthographic projection of a portion of the second inorganic packaging sub-layer within the non-display region on the substrate overlaps with both an orthographic projection of the first inorganic insulating sub-layer on the substrate and an orthographic projection of the second inorganic insulating sub-layer on the substrate.

21. A display panel, comprising a display region and a non-display region, and further comprising:
a substrate;
a light-emitting unit, arranged on a side of the substrate and located within the display region;
a packaging layer, comprising an organic packaging sub-layer covering the light-emitting unit; and
a dam structure, arranged on the side of the substrate and located within the non-display region, the dam structure comprising a first dam, and the first dam comprising a first metal layer and a first insulating layer arranged in a stacked manner.

22. The display panel according to claim 21, wherein the dam structure further comprises a second dam adjacent to the first dam, and an overflow groove is formed between the first dam and the second dam.

23. The display panel according to claim 22, wherein the second dam is located on a side of the first dam away from the display region, and a height of the second dam is higher than a height of the first dam;
the height of the first dam satisfies: 3.5 um≤H335 um; the height of the second dam satisfies: 5.5 um≤H4≤8.5 um; the second dam comprises a second metal layer and a second insulating layer arranged in a stacked manner,
a thickness of the first metal layer is equal to a thickness of the second metal layer, and
a thickness of the second insulating layer is larger than a thickness of the first insulating layer.

24. The display panel according to claim 22, further comprising a third insulating layer, wherein the third insulating layer is located between the dam structure and the substrate in a direction perpendicular to the substrate, a groove is provided on a side of the third insulating layer away from the substrate, and the overflow groove comprises the groove.

25. The display panel according to claim 23, wherein the first insulating layer comprises a first organic insulating sub-layer and a first inorganic insulating sub-layer, the second insulating layer comprises a second organic insulating sub-layer and a second inorganic insulating sub-layer, the first metal layer, the first organic insulating sub-layer and the first inorganic insulating sub-layer are arranged in a stacked manner, and the second metal layer, the second organic insulating sub-layer and the second inorganic insulating sub-layer are arranged in a stacked manner; and
a thickness of the second organic insulating sub-layer in the direction perpendicular to the substrate is larger than a thickness of the first organic insulating sub-layer in the direction perpendicular to the substrate.

26. A display device, comprising the display panel according to claim 1.
